(19) United States
(12) Patent Application Publication
(10) Pub. No.: US 2010/0171232 A1
(43) Pub. Date: Jul. 8, 2010

(54) METHOD FOR SEMICONDUCTOR SOLIDIFICATION WITH THE ADDITION OF DOPED SEMICONDUCTOR CHARGES DURING CRYSTALLISATION

(75) Inventors: Florence Servant, Grenoble (FR); Denis Camel, Chambery (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: COMMISSARIAT A L' ENERGIE ATOMIQUE, Paris (FR)

(21) Appl. No.: 12/646,278

(22) Filed: Dec. 23, 2009

(30) Foreign Application Priority Data
Jan. 5, 2009 (FR) 09 50016

(51) Int. Cl. C30B 31/04

(52) U.S. Cl. 264/104

(57) ABSTRACT

A method for semiconductor solidification which includes steps for:
forming a bath of molten semiconductor from a first charge of semiconductor which includes dopants,
solidification of the molten semiconductor,
and which in addition includes, during solidification, the implementation of one or more steps for the addition of supplementary charges of semiconductor, which also contains dopants, to the molten semiconductor bath.

### TECHNICAL FIELD

This document relates to a method of solidification of a semiconductor, in particular silicon, which allows doping of the semiconductor to be controlled during its solidification. Such method applies in particular to the crystallisation of liquid phase metallurgical silicon in the form of ingots or ribbons used for the manufacture of photovoltaic cell substrates.

### THE STATE OF THE PRIOR ART

During a directed solidification of a semiconductor containing one or more dopants, the dopant concentration varies along the direction of crystallisation due to the fact that the composition of the solid that is formed differs from that of the liquid (there is generally an accumulation of dopants in the liquid in the most general case). More specifically, in the case of complete mixture of the liquid, the distribution of dopants in this ingot along the direction of crystallisation is governed by the Scheil-Gulliver equation which, for each type of dopant, uses its partition coefficient k=S_{S}/S_{L}, where S_{S} is the solubility of the dopant species in the solid silicon and S_{L} the solubility of the dopant species in the liquid silicon (molten). Boron and phosphorous both have a lower solubility in solid silicon than in liquid silicon, which is expressed as a partition coefficient of less than 1.

For a given dopant species, the Scheil-Gulliver equation is expressed in the following form:

C_{S}=k·C_{LO}·(1−f_{S})^{k-1}, where:

C_{S}: Concentration of the dopant species in the solid crystallised semiconductor,

C_{LO}: Initial concentration of the dopant species in the liquid semiconductor,

k: partition coefficient of the dopant species,

f_{S}: fraction of the crystallised semiconductor relative to the total amount of semiconductor (liquid+solid).

This concentration variation results in a variation of electrical properties such as conductivity. Furthermore, it leads to the upper part of the ingot, where this concentration increases very sharply, being rejected, which reduces the material yield of the method.

Current standard photovoltaic cells are generally made from substrates produced from purified metallurgical silicon ingots. This type of silicon contains impurities, and in particular dopant species or dopants, which give the silicon a certain electrical conductivity.

A semiconductor is described as being “compensated” when it contains both electron acceptor dopants and electron donor dopants. The free carrier concentration in such a semiconductor corresponds to the difference between the number of electrons and the number of holes provided by dopants, which are generally boron (p-type, that is, electron acceptor) and phosphorous (n-type, that is, electron donor) when the semiconductor is silicon.

The partition coefficient for phosphorous, kₚ, is equal to 0.35, and the partition coefficient for boron, k_{b}, is equal to 0.8.

During the crystallisation of an uncompensated p-type silicon ingot, the ingot includes only boron as a dopant species. The distribution of boron atoms in the ingot is fairly homogeneous over the majority of the height of the ingot since there is little segregation of this element in the silicon, given that the partition coefficient for boron is 0.8.

But during the manufacture of an ingot of silicon which contains phosphorous, that is, either compensated or uncompensated n-type silicon, or compensated p-type silicon, given that phosphorous segregates more than boron (kₚ=0.35), the resistivity of the ingot obtained is therefore non-homogeneous over the height of the silicon ingot.

Furthermore, at the start (that is, the part which crystallised first) of an ingot of p-type compensated silicon, the boron concentration is greater than the phosphorous concentration. Given that the phosphorous segregates to a greater extent than the boron, the silicon will be, after a certain solidified height, richer in phosphorous than in boron, giving rise to a change in the type of conductivity in the ingot. Part of the ingot will therefore be unusable. Furthermore, this effect will be accentuated (with a change in the type of conductivity even closer to the start of the ingot) if the difference between the boron and phosphorous concentrations at the start of the ingot is small, that is, when one wishes to obtain high-resistivity silicon, for the manufacture, for example, of photovoltaic cells (resistivity greater than about 0.1 Ohm·cm). This effect will be even more accentuated if the silicon contains a lot of phosphorous for a given resistivity.

Although this change in the type of conductivity is not observed in n-type ingots, since the phosphorous concentration always stays greater then that of boron, the difference between these concentrations will be greater at the top of the ingot than at the start of the ingot, resulting in non-homogeneous resistivity, which decreases along the height of the ingot.

Thus in all cases a large part of the ingot is unusable, whether because of non-homogeneity in resistivity or because of a change in the type of conductivity.

Document WO 2007/001184 A1 describes a method for the manufacture of semiconductor ingots in which, in order to reduce the non-homogeneity of resistivity and to push back the location of the change in conductivity in the ingot, n- or p-type dopants are added during the crystalline growth of the silicon. Although these additions of dopants mean that the balance between the dopant species in the semiconductor bath during growth is better controlled in comparison with growth without additions which obeys the Scheil-Gulliver equation, the total number of dopant species however, becomes much greater than without addition, which affects the electrical properties of devices made from the crystallised silicon that is obtained, in particular mobility.

### PRESENTATION OF THE INVENTION

Thus there is a need to propose a method which is used for the solidification, for example crystallisation in the form of ingots, of a semiconductor in accordance with the type of conductivity desired, and which has homogeneous resistivity throughout the solidified semiconductor, whilst preventing changes in the type of conductivity over the entire or a very large part of the semiconductor and which does not adversely effect the electrical properties of devices made from the semiconductor that is obtained.

Moreover, there is a need to propose an improved method for directed crystallisation of doped semiconductors in which the variation of free carrier density along the direction of crystallisation, over all or part of the ingot, is smaller than in conventional methods without addition during the course of crystallisation, whilst ensuring that the variation of the total free carrier density is lower than when the variation in the free carrier density is corrected by the addition of pure dopants.

In order to achieve this, one embodiment proposes a semiconductor solidification method which includes at least steps for:
forming a bath of molten semiconductor from at least one first charge of semiconductor which includes dopants,
solidification of the molten semiconductor,
   and which in addition includes, during the solidification of the molten semiconductor, the use, during at least part of the solidification method, of one or more steps for the addition of one or more supplementary charges of the semiconductor, also containing dopants, to the molten semiconductor bath, which lowers the variability of the value of the

$${\sum }_{i = 1}^{n} {k}_{i} {C}_{L}^{i} - {\sum }_{j = 1}^{m} {k}_{j} {C}_{L}^{j}$$

term of the molten semiconductor in the bath relative to the variability naturally achieved by the values of the partition coefficients for the dopant species so that:

$$( {\sum }_{i = 1}^{n} {k}_{i} {C}_{a}^{i} - {\sum }_{j = 1}^{m} {k}_{j} {C}_{a}^{j} ) < ( {\sum }_{i = 1}^{n} {k}_{i} {C}_{L}^{i} - {\sum }_{j = 1}^{m} {k}_{j} {C}_{L}^{j} ) if$$

$${\sum }_{i = 1}^{n} {k}_{i} ( 1 - {k}_{i} ) {C}_{L}^{i} > {\sum }_{j = 1}^{m} {k}_{j} ( 1 - {k}_{j} ) {C}_{L}^{j} \\ ( {\sum }_{i = 1}^{n} {k}_{i} {C}_{a}^{i} - {\sum }_{j = 1}^{m} {k}_{j} {C}_{a}^{j} ) > ( {\sum }_{i = 1}^{n} {k}_{i} {C}_{L}^{i} - {\sum }_{j = 1}^{m} {k}_{j} {C}_{L}^{j} ) if$$

$${\sum }_{i = 1}^{n} {k}_{i} ( 1 - {k}_{i} ) {C}_{L}^{i} < {\sum }_{j = 1}^{m} {k}_{j} ( 1 - {k}_{j} ) {C}_{L}^{j}$$

and which lowers the value of the

$${\sum }_{i = 1}^{n} {k}_{i} {C}_{L}^{i} - {\sum }_{j = 1}^{m} {k}_{j} {C}_{L}^{j}$$

term of the molten semiconductor in the bath relative to the variability achieved by the addition of pure dopant species so that:

$${\sum }_{i = 1}^{n} {k}_{i} {C}_{a}^{i} < {\sum }_{i = 1}^{n} {k}_{i} {C}_{L}^{i} and {\sum }_{j = 1}^{m} {k}_{j} {C}_{a}^{j} < 2 {\sum }_{i = 1}^{n + m} {k}_{i} {C}_{L}^{i} if$$

$${\sum }_{i = 1}^{n} {k}_{i} ( 1 - {k}_{i} ) {C}_{L}^{i} > {\sum }_{j = 1}^{m} {k}_{j} ( 1 - {k}_{j} ) {C}_{L}^{j} ;$$

$${\sum }_{j = 1}^{m} {k}_{j} {C}_{a}^{j} < {\sum }_{j = 1}^{m} {k}_{j} {C}_{L}^{j} and {\sum }_{i = 1}^{n} {k}_{i} {C}_{a}^{i} < 2 {\sum }_{i = 1}^{n + m} {k}_{i} {C}_{L}^{i} if$$

$${\sum }_{i = 1}^{n} {k}_{i} ( 1 - {k}_{i} ) {C}_{L}^{i} < {\sum }_{j = 1}^{m} {k}_{j} ( 1 - {k}_{j} ) {C}_{L}^{j}$$

where C_{L}ⁱ: concentration of electron acceptor dopants i in the molten semiconductor bath;

C_{L}^{j}: concentration of electron donor dopants j in the molten semiconductor bath;

Cₐⁱ: concentration of electron acceptor dopants i in the supplementary added charge or charges;

Cₐ^{j}: concentration of electron donor dopants j in the supplementary added charge or charges;

kᵢ: partition coefficient of the electron acceptor dopants i,

kⱼ: partition coefficient of the electron donor dopants j,

Thus depending on the relative composition between the dopants in the bath (rich in electron-acceptor dopants in the case where

$${\sum }_{i = 1}^{n} {k}_{i} ( 1 - {k}_{i} ) {C}_{L}^{i} > {\sum }_{j = 1}^{m} {k}_{j} ( 1 - {k}_{j} ) {C}_{L}^{j} ,$$

or rich in electron-donor dopants j in the case where

$${\sum }_{i = 1}^{n} {k}_{i} ( 1 - {k}_{i} ) {C}_{L}^{i} < {\sum }_{j = 1}^{m} {k}_{j} ( 1 - {k}_{j} ) {C}_{L}^{j} ) ,$$

the dilution will have an effect on the decrease in the variability of the free carrier density if the composition of the added charge in terms of dopant species i, Cⁱₐ, is such that the first solid formed from it would have a free carrier density which is less than the solid formed by the bath without the addition in the rich-in-electron-acceptor dopants case, or greater than the solid formed by the bath without additions in the rich-in-electron-donor dopants case, that is:

$$( {\sum }_{i = 1}^{n} {k}_{i} {C}_{a}^{i} - {\sum }_{j = 1}^{m} {k}_{j} {C}_{a}^{j} ) < ( {\sum }_{i = 1}^{n} {k}_{i} {C}_{L}^{i} - {\sum }_{j = 1}^{m} {k}_{j} {C}_{L}^{j} )$$

in the rich-in-electron-acceptor dopants i case, or

$$( {\sum }_{i = 1}^{n} {k}_{i} {C}_{a}^{i} - {\sum }_{j = 1}^{m} {k}_{j} {C}_{a}^{j} ) > ( {\sum }_{i = 1}^{n} {k}_{i} {C}_{L}^{i} - {\sum }_{j = 1}^{m} {k}_{j} {C}_{L}^{j} )$$

in the rich-in-electron donor dopants j case.

Dilution will also have an effect on the total number of free carriers:

$${\sum }_{i = 1}^{n} {k}_{i} {C}_{a}^{i} < {\sum }_{i = 1}^{n} {k}_{i} {C}_{L}^{i}$$

in the case of a bath which is rich in electron acceptor dopants i, and

$${\sum }_{j = 1}^{m} {k}_{j} {C}_{a}^{j} < {\sum }_{j = 1}^{m} {k}_{j} {C}_{L}^{j}$$

in the case of a bath which is rich in electron donor dopants j.
Furthermore, by imposing the conditions

$${\sum }_{j = 1}^{m} {k}_{j} {C}_{a}^{j} < 2 {\sum }_{i = 1}^{n + m} {k}_{i} {C}_{L}^{i} when$$

$${\sum }_{i = 1}^{n} {k}_{i} ( 1 - {k}_{i} ) {C}_{L}^{i} > {\sum }_{j = 1}^{m} {k}_{j} ( 1 - {k}_{j} ) {C}_{L}^{j} , and$$

$${\sum }_{i = 1}^{n} {k}_{i} {C}_{a}^{i} < 2 {\sum }_{i = 1}^{n + m} {k}_{i} {C}_{L}^{i} when$$

$${\sum }_{i = 1}^{n} {k}_{i} ( 1 - {k}_{i} ) {C}_{L}^{i} < {\sum }_{j = 1}^{m} {k}_{j} ( 1 - {k}_{j} ) {C}_{L}^{j} ,$$

limits are thus created for the concentration of the dopants so that there is always a dilution phenomenon. Given that the speed of solidification is directly linked to the addition concentrations, the limits for this are also set.

Thus, first of all at least two sub-charges of different mean compositions in terms of dopant concentrations are selected. A semiconductor bath is then formed by melting a first of the sub-charges, for example in a crucible. The solidification of this first sub-charge is then started and then, during solidification, the second sub-charge is added, preferentially in a continuous manner throughout the crystallisation, to the semiconductor bath, thus adding dopants to the semiconductor bath, but also achieving dilution of these dopants, given that the quantity of molten silicon in the bath is increased.

The addition of doped silicon rather than pure dopants means that the mobility of the majority carrier is not affected since, unlike in the prior art, the concentrations of dopants in the molten semiconductor bath is not or only slightly increased.

This method compensates for the addition of dopants to the bath during solidification (due to segregation) by the addition of a non-negligible amount of semiconductor. In effect, this addition of semiconductor lowers the concentration of dopants by semiconductor dilution in the bath, and therefore the total number of majority carriers in the semiconductor bath, corresponding to the term

$${\sum }_{i = 1}^{n} {k}_{i} {C}_{L}^{i} + {\sum }_{j = 1}^{m} {k}_{j} {C}_{L}^{j} ,$$

is maintained at an effectively constant level, which does not adversely effect the electrical properties of devices, for example photovoltaic cells, made from the solidified semiconductor that is obtained. For example, the doping of the charge that is added in non-negligible quantities may include less electron donor dopants than the initial charge for a given level of electron acceptor dopants, irrespective of the type of conductivity of the charge. Thus only the necessary amounts of electron acceptor dopants are added as a result of this dilution. Furthermore, this method means that recycled charges can be used to carry out this solidification.

It is therefore possible to obtain p-type uncompensated solidified silicon which exhibits variability in its resistivity and in the number of free carriers of less than 10% over about more than 90% of its height. It is also possible to obtain p-type compensated solidified silicon with a ratio of the number of electron acceptor dopants to the number of electron donor dopants of between 0.6 and 3, which exhibits variability in resistivity of less than 20% and variability in the total number of carriers of less than about 50% over about more than 70% of its height.

This method also allows the material yield of the solidification to be increased, since only a very small part of the solidified semiconductor is stripped away, given that a major part of the solidified semiconductor exhibits the desired electrical properties.

More generally, using charges of silicon which are heterogeneous in terms of doping, the method means that semiconductor ingots may be solidified which are of constant resistivity over a large part of their height, despite the dopant segregation phenomenon (irrespective of the dopant, even if other than boron or phosphorous).

This method applies to any type of semiconductor solidification method, and in particular to any type of liquid phase crystallisation method.

The method described above is described in general terms when one or more electron donor dopants i and one or more electron acceptor dopants j are used. In the case where only boron is used as an electron acceptor dopant i and only phosphorous is used as an electron donor dopant j, the indices n and m are then equal to 1, and the parameters of index i then correspond to the parameters for boron (k_{B}, C_{L}^{B}, Cₐ^{B}) and parameters of index j then correspond to the parameters for phosphorous (k_{P}, C_{L}^{P}, Cₐ^{P}).

The supplementary charge or charges of semiconductor may be added whilst ensuring that the following relationships are observed:

$${C}_{a}^{P} = {C}_{a}^{B} \frac{( 1 - {k}_{P} ) {C}_{L}^{P}}{( 1 - {k}_{B} ) {C}_{L}^{B}} + {C}_{L}^{P} * \frac{( {k}_{P} - {k}_{B} )}{( 1 - {k}_{B} )} , and$$

$$\frac{d {m}_{a}}{d {m}_{S}} = \frac{{C}_{L}^{B} ( 1 - {k}_{B} )}{( {C}_{L}^{B} - {C}_{a}^{B} )} > 1 - {k}_{P} , where \text{:}$$

$$d {m}_{a} / d t \text{:} addition speed in kg \text{/} s$$

$$d {m}_{S} / d t \text{:} crystallisation speed in kg \text{/} s$$

Thus, by ensuring that these relationships are observed, the supplementary semiconductor charge or charges are added at an addition speed which keeps the value of the terms k_{B}C_{L}^{B} et k_{P}C_{L}^{P} approximately constant during at least part of the solidification method.

The supplementary charge or charges of semiconductor may be added at an addition speed such that:

$$\frac{d {m}_{a}}{d {m}_{S}} < 1 ,$$

that is, with an addition speed less than the speed of crystallisation, which corresponds to concentrations of added dopants such that:

$${C}_{a}^{P} < {k}_{P} {C}_{L}^{P} and {C}_{a}^{B} < {k}_{B} {C}_{L}^{B} .$$

Such an addition speed enables in particular that additions are completed before the end of crystallisation.

The supplementary semiconductor charge or charges may be added to the semiconductor bath in solid form, then may be fused and mixed with the bath of molten semiconductor.

The supplementary semiconductor charge or charges may be added to the semiconductor bath in liquid form, during at least one part of the solidification method. In one preferential embodiment, this addition in the liquid form is carried out in a continuous manner.

When several supplementary charges of the semiconductor are added during solidification, a supplementary semiconductor charge may be added each time that the mass of solidified semiconductor increases by at most 1% in relation to the total mass of solidified semiconductor obtained at the end of the solidification method.

The steps in the solidification method may be carried out in Bridgman type furnace, where the semiconductor bath may be located in a crucible of said furnace.

The furnace may include a closed enclosure which is under an argon atmosphere in which the crucible is arranged.

When the supplementary semiconductor charge or charges are added to the semiconductor bath in solid form, this addition or these additions may be carried out using a distribution device which can also carry out preheating of the supplementary semiconductor charge or charges.

In this case the moments in time at which the addition or additions of the supplementary semiconductor charge or charges are made may be determined by control means of the distribution device.

The concentration of at least one type of dopant in the first semiconductor charge may be different to the concentration of this same type of dopant in the supplementary semiconductor charge or charges.

The concentration of dopants with one type of conductivity in the first semiconductor charge may be greater than or equal to the concentration of dopants with this same type of conductivity in the supplementary semiconductor charge or charges.

The molten semiconductor may be solidified in the form of an ingot or a ribbon.

### BRIEF DESCRIPTION OF THE DRAWINGS

The present invention will be better understood by reading the description of embodiments, which are given for purely informative purposes and which are in no way limitative, whilst referring to the appended diagrams in which:

FIG. 1 represents a Bridgman type furnace in which a semiconductor solidification method according to one particular embodiment is carried out,

FIGS. 2 to 4 represent simulation curves of dopant concentrations and of resistivity along the silicon ingots which are solidified in accordance with a method according to one particular embodiment and along ingots which are solidified in accordance with a method from the prior art.

Identical, similar or equivalent parts of the various figures described hereafter bear the same numerical references so as to facilitate moving from one figure to another.

In order to make the figures more readable, the various parts represented in the figures are not necessarily shown at a uniform scale.

The different possibilities (variants and embodiments) must be understood as not being exclusive of each other and may be combined together.

### DETAILED DESCRIPTION OF SPECIFIC EMBODIMENTS

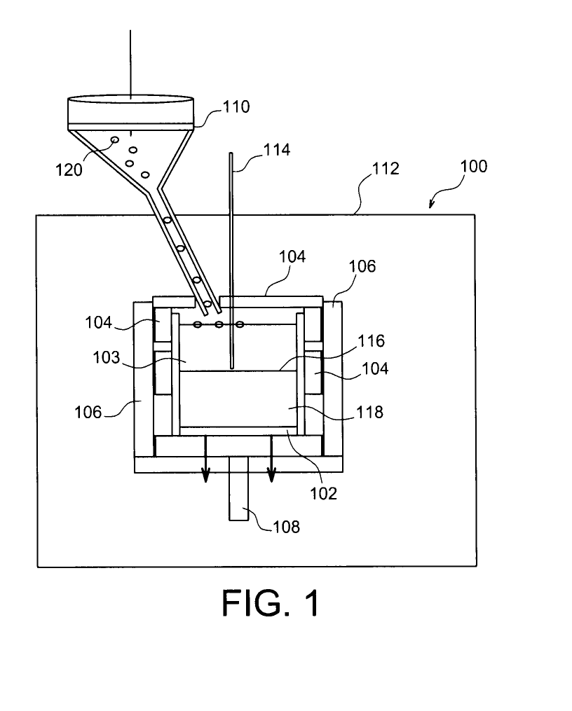

Reference is first of all made to FIG. 1 which represents a Bridgman type furnace 100, or zone fusion furnace, in which a semiconductor solidification method, here a crystallisation, is carried out.

The furnace 100 includes a crucible 102 designed to hold molten semiconductor 103 to be crystallised. In FIG. 1, crystallised semiconductor 118 is also found in the crucible 102, beneath the bath of semiconductor 103. The furnace 100 also includes heating elements 104, which are, for example electrically supplied, arranged above the crucible 102 and against an upper part of the side walls of the crucible 102. These heating elements 104 are used to fuse the semiconductor when it is introduced in solid form into the crucible 102, and to maintain it in a molten form. The furnace 100 also includes thermally insulating side walls 106.

The furnace 100 includes a cooling system 108 located beneath the crucible 102, used to crystallise the semiconductor by channelling the flow of heat downwards (parallel to the axis of growth of the semiconductor) thus promoting the growth of columnar grains in the semiconductor. Thus the molten semiconductor 103 located in the crucible 102 gradually crystallises starting from the bottom of the crucible 102. The furnace 100 also includes a closed enclosure 112 such that the semiconductor to be crystallised is located in an atmosphere of inert gas, for example argon.

The furnace 100 includes, in addition, a distribution device 110 located above the crucible 102. This distribution device 110 allows supplementary semiconductor charges 120 to be added to the crucible 102 during the semiconductor crystallisation method. The supplementary charges 120 are here added in solid form and have, for example, dimensions smaller than about 10 cm, and preferentially smaller than about 1 cm, so that supplementary charges may melt rapidly in the semiconductor bath 103. The distribution device 110 is preferentially gradually filled as the crystallisation method is carried out by means of a sealed airlock which has its own system for pumping and for introducing argon. Furthermore, this distribution device 110 is also used to pre-heat the semiconductor that it is intended to introduce into the crucible 102 during the course of the solidification method.

In one variant, the supplementary semiconductor added during the crystallisation method may be in liquid form, with this supplementary semiconductor being in this case fused outside the semiconductor bath, and then added in the form of a continuous or discontinuous melt to the semiconductor bath.

Finally the furnace 100 includes a sensor rod 114, for example made of silica, installed above the crucible 102, and which is used to find the position of the solidification front 116 of the semiconductor, that is, the boundary between the molten semiconductor 103 and the crystallised semiconductor 118, as a function of the crystallisation time.

The method for crystallisation of the semiconductor that is implemented in the furnace 100 will now be described.

A first semiconductor charge, for example of silicon, which includes dopants, is placed in the crucible 102. This first silicon charge is then fused using the heating elements 104, forming a bath of molten silicon 103. In one variant it is also possible to pour molten silicon directly into the crucible 102. The method of crystallisation of the molten semiconductor is then started. At the end of a certain crystallisation time, a small quantity of pre-heated silicon is added using the distribution device 110 placed above the molten silicon bath. This silicon which arrives in the bath of molten silicon in solid form then floats at the surface of the silicon bath 103 since its density is less than the molten silicon. This supplementary charge of silicon will then fuse and be mixed with the silicon bath 103 in order to be subsequently crystallised. The addition of silicon will then be repeated at a given frequency in order to maintain an approximately constant concentration of dopant in the crystallised ingot.

By an appropriate choice of the dopant concentrations and of the masses of the silicon charges used, as well as the moments in time at which the supplementary charges are added, the values of the terms k_{B}C_{L}^{B}−k_{P}C_{L}^{P} and k_{B}C_{L}^{B}+k_{P}C_{L}^{P} in the molten semiconductor bath may be kept approximately constant throughout the entire or during a large part of the crystallisation method. C_{L}^{B} and C_{L}^{P} correspond respectively to the electron acceptor and donor dopant concentrations in the molten semiconductor found in the crucible 102. k_{B} and k_{P} correspond respectively to the partition coefficients of these electron acceptor and donor dopants.

The addition of supplementary semiconductor charges may be carried out one or more times during the crystallisation method. The various charges added may in particular have different masses and/or dopant concentrations, with, for example a material flow (quantity of added semiconductor) which is at most equal to the production flow of the crystallised material.

The various semiconductor charges which are used in this crystallisation method are selected depending on their dopant species concentrations, their respective partition coefficients and the desired final properties for the crystallised semiconductor (homogeneity of composition and electrical properties). Homogeneity is optimised by the choice of the moment in time at which the addition of supplementary semiconductor commences and of the speed at which this addition is made, where this addition may be continuous or discontinuous.

All these parameters are chosen depending on the desired resistivity and concentration of dopants in the ingot of crystallised semiconductor. The calculations used to select the type of semiconductor charges to be used to carry out this crystallisation method are described below.

First of all the resistivity ρ_{O} of the ingot that it is desired to obtain, and whose value depends on the number of free carriers na−nd, is selected. The relationship is as follows:

$${ρ}_{0} = \frac{1}{\vert na - nd \vert \times q \times μ ( T )} \qquad ( 1 )$$

where
q: charge of an electron
μ: mobility of the majority carriers
na−nd: number of the majority carriers

The mobility μ, whose value depends on the total density of the majority carriers na+nd, is defined by the following empirical relationship:

$$μ ( T ) = {μ}_{min} {T}_{n}^{β1} + \frac{( {μ}_{max} - {μ}_{min} ) {T}_{n}^{β 2}}{1 + {( \frac{na + nd}{{N}_{ref} {T}_{n}^{β3}} )}^{α {T}_{n}^{β 4}}} \qquad ( 2 )$$

where Tn: the temperature normalised to 300 K. The constants used in this relationship depend on the nature of the carriers (electrons for n-type or holes for p-type) and are equal to the values presented in the following table:

| | | | | | Temperature | |
|---|---|---|---|---|---|---|
| | | Majority carriers | | | β..1 | β2 |
| | μₘₐₓ | μₘᵢₙ | N_{ref} (cm-3) | α | β3 | β4 |
| Electrons | 1417 | 60 | 9.64 * 10^{E}16 | 0.664 | −0.57 | −2.2 |
| Holes | 470 | 37.4 | 2.82 * 10^{E}16 | 0.642 | 2.4 | −0.146 |

The terms na and nd respectively represent the number of electron donor and electron acceptor dopant atoms, and are respectively comparable with the number of boron and phosphorous atoms in the crystallised silicon. For a unit volume it may be assumed that the dopant concentrations in the crystallised silicon correspond to na and nd:

na=C_{S}^{B}=k_{B}C_{L}^{B}(t) and nd=C_{S}^{P}=k_{P}C_{L}^{P}(t), expressed in ppma.

Given that the partition coefficients for boron and phosphorous are different (k_{B}=0.8 and k_{P}=0.35), the value of the na−nd term is therefore not constant during a crystallisation method which does not include steps for the addition of supplementary semiconductor charges during crystallisation. This is expressed during such a method by the enrichment of the liquid silicon with phosphorous, with this enrichment subsequently being reflected in the crystallised silicon. This enrichment is described by the Scheil-Gulliver equation by the relationship:

C_{S}^{i(g)}=k_{B}C_{LO}ⁱ(1−f_{S})ᵢ^{k-1} (3)

where

i: the dopant species (i=B or P),

f_{S}: the solidified fraction of semiccnductor, and

C_{LO}ⁱ: the initial species i concentration in the liquid.

By carrying out additions of supplementary charges of semiconductor which include dopants during crystallisation, compensation for the phosphorous enrichment described above is achieved, by means, for example, of the addition of silicon which is less doped with phosphorous (ore more highly doped with boron) in order to keep the value of the na−nd or k_{B}C_{L}^{B}−k_{P}C_{L}^{P} term lower than without addition and the value of the na+nd or k_{B}C_{L}^{B}+k_{P}C_{L}^{P} term lower than with the addition of pure dopants, in the semiconductor bath during crystallisation.

Depending on the characteristics of the first charge used or of the liquid bath at the moment in time when the addition is made:
mass (M₁ or M_{L}),
dopant concentrations (C₁^{B}, Cᵢ^{P}) or (C_{L}^{B}, C_{L}^{P})
   and on the desired characteristics for the crystallised semiconductor:
initial resistivity ρ₀,
fluctuations of na−nd at the instant in time t due to the addition of a discontinuous charge,
change in na−nd between two heights of the ingot,

appropriate supplementary charges (Cₐ^{B},Cₐ^{P}), variable or constant, are chosen to be added during the method and a variable or constant addition speed relative to the crystallisation speed (dmₐ/dmₛ) is chosen.

To obtain the speed of addition and the concentration of the supplementary charge at the moment in time t, a solute balance in the liquid part of the silicon is drawn up. This solute balance is drawn up for both dopants i=B, P as:

d(C_{L}ⁱm_{L})=Cₐⁱdmₐ−kᵢC_{L}ⁱdm_{S} (4)
dmₐ: mass added during the time dt,
Cₐⁱ: concentration of species i in charge added,
dm_{S}: mass solidified during the time dt
   Concentrations are expressed here as ppma (parts par million atoms).

This balance signifies that the variation of the number of atoms of dopant i in the liquid is equal to the number of atoms of dopant i provided by the addition minus the number of atoms of dopant i crystallised in the time interval dt.

The term m_{L} (t) may be expressed as a function of the other semiconductor masses brought into play, by the equation:

m_{L}(t)=M₁+mₐ(t)−m_{S}(t) (5)

where M₁: the mass of the first charge (constant),

mₐ (t): the total mass of silicon added at the moment in time t (where at the end of the addition t_{f}: mₐ(t_{f})=M₂)

m_{S} (t): the total mass of silicon crystallised at the moment in time t (where at the end of the addition t_{f}: m_{S}(t_{f})=M₁+M₂)

Form the equations (4) and (5) given above, the variation in the liquid dC_{L}ⁱ(t) as a function of dm_{S}(t) and dmₐ(t) can be described:

m_{L}(t)*dC_{L}ⁱ(t)=C_{L}ⁱ(t)*(1−kᵢ)*dm_{S}(t)+(Cₐⁱ−C_{L}ⁱ)*dmₐ(t) (6)

To give a value of the variation of k_{B}C_{L}^{B}−k_{P}C_{L}^{P} for two dopants, the following is obtained:

m_{L}(t)*d(k_{B}C_{L}^{B}−k_{P}C_{L}^{P})=(k_{B}(1−k_{B})C_{L}^{B}−k_{P}(1−k_{P})C_{L}^{P})dm_{S}−(k_{B}(C_{L}^{B}−Cₐ^{B})−k_{P}(C_{L}^{P}−Cₐ^{P}))*dmₐ (7)

The first term represents the variation of k_{B}C_{L}^{B}−k_{P}C_{L}^{P} brought about by the Scheil equation for a corresponding given liquid mass m_{L} in the no-additions case. The second terms represents the variation of k_{B}C_{L}^{B}−k_{P}C_{L}^{P} brought about by the additions of doped silicon. In order to obtain an improvement relative to the no-additions case, this second term must be positive if there is a bath rich in boron (k_{B}(1−k_{B})C_{L}^{B}−k_{P}(1−k_{P})C_{L}^{P}>0 or negative if the bath is rich in phosphorous (k_{B}(1−k_{B})C_{L}^{B}−k_{P}(1−k_{P})C_{L}^{P}<0.

The optimum addition speed resulting from this is equal to:

$${d m}_{a} ( t ) = \frac{{C}_{L}^{B} ( t ) {k}_{B} ( 1 - {k}_{B} ) - {C}_{L}^{P} ( t ) {k}_{P} ( 1 - {k}_{P} )}{( {k}_{B} ( {C}_{L}^{B} - {C}_{a}^{B} ) - {k}_{P} ( {C}_{L}^{P} - {C}_{a}^{P} )} * {d m}_{S}$$

in the case where k_{B}C_{L}^{B}−k_{P}C_{L}^{P} remains constant.

The same balance (6) can be used to establish the variation in the value of the k_{B}C_{L}^{B}+k_{P}C_{L}^{P} term and to compare it with a given variation of k_{B}C_{L}^{B}−k_{P}C_{L}^{P} in the case of addition of pure dopants, and the following is deduced:

That Cₐ^{P}<C_{L}^{P} in the case of a bath rich in phosphorous and that Cₐ^{B}<C_{L}^{B} in the case of a bath rich in Boron.

In the case where k_{B}C_{L}^{B} and k_{P}C_{L}^{P} are kept constant throughout crystallisation, these terms are always equal to k_{B}C₁^{B} and k_{P}C₁^{P}. Then equation (6) takes the following form, for each species i:

$$\frac{d {m}_{a} ( t )}{d {m}_{S} ( t )} = \frac{{C}_{1}^{i} ( t ) * ( 1 - {k}_{i} )}{( {C}_{1}^{i} - {C}_{a}^{i} )}$$

with an addition speed relative to the crystallisation speed which is constant and which is less than 1 in order to finish additions before the crystallisation.

The concentration of the added charge must therefore satisfy the relationship:

$${C}_{a}^{p} = {C}_{a}^{B} \frac{( 1 - {k}_{P} ) {C}_{1}^{P}}{( 1 - {k}_{B} ) {C}_{1}^{B}} + {C}_{1}^{P} * \frac{( {k}_{P} - {k}_{B} )}{( 1 - {k}_{B} )}$$

where the addition speed is:

$$\frac{d {m}_{a}}{d {m}_{S}} = \frac{{C}_{L}^{B} ( 1 - {k}_{B} )}{( {C}_{L}^{B} - {C}_{a}^{B} )} > 1 - {k}_{P}$$

In this case the total mass of added charges is:

$$\frac{{M}_{2}}{{M}_{1} + {M}_{2}} = \frac{{C}_{L}^{B} ( 1 - {k}_{B} )}{( {C}_{L}^{B} - {C}_{a}^{B} )}$$

preferentially distributed as charges of very small quantities.

A first embodiment of the creation of an uncompensated silicon p-type ingot will now be described, that is one which only contains boron as a dopant species, and whose desired resistivity is equal to about 3.32 Ohm·cm.

The initially molten charge is of microelectronic silicon doped only with boron at a concentration of 0.04 ppmw (that is 5.2^{E}15 atoms/cm³). The mass of the first charge is equal to half the final mass of the ingot. The supplementary charges that are added to the silicon bath during the crystallisation method are similarly based on electronic origin silicon, also doped only with boron, but at a concentration of 0.004 ppmw. The total mass of these supplementary charges represents half of the final mass of the ingot.

The additions of supplementary charges is carried out each time the mass of the crystallised semiconductor increases by about 0.2% relative to the total mass of crystallised semiconductor obtained at the end of the crystallisation method. These additions commence as soon as crystallisation starts.

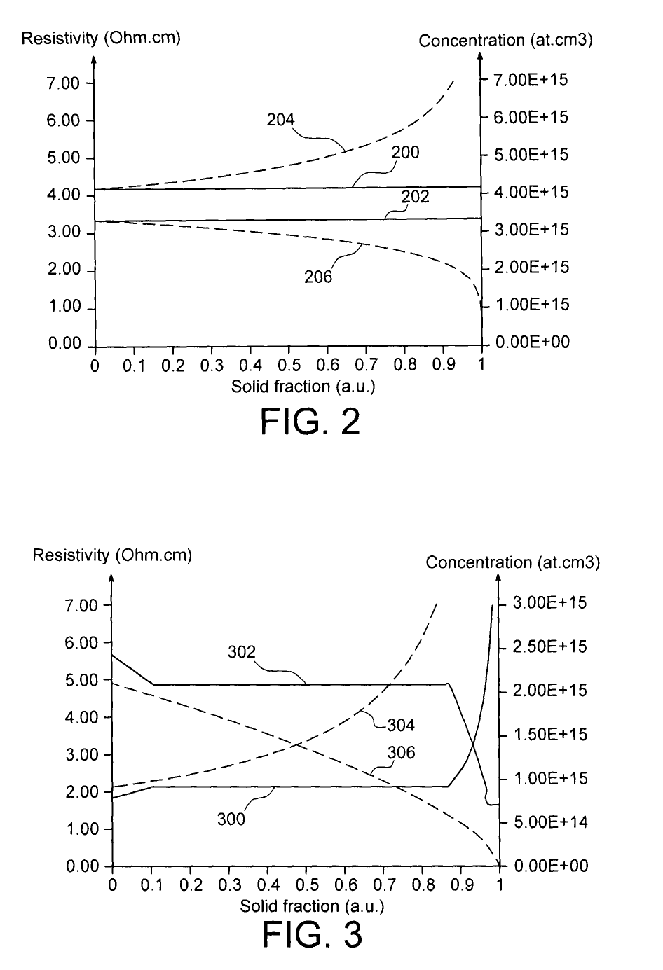

The curve 200 in FIG. 2 represents the boron concentration in the crystallised silicon (right vertical axis) as a function of the ingot height (horizontal axis, with a normalised scale). Thus it can be seen that the ingot obtained exhibits a constant boron concentration equal to about 4.2^{E}15 atoms/cm³ over the entire height of the ingot. In an analogous manner, curve 202 in FIG. 2 represents the resistivity of the crystallised silicon (left vertical axis) as a function of the ingot height. It can be seen from this curve 202 that the ingot obtained exhibits a constant resistivity equal to about 3.32 Ohm·cm over the entire height of the ingot.

In comparison, curve 204 represents the boron concentration in an ingot of silicon obtained by crystallisation of a molten charge whose nature is similar to that of the initial charge described above, but without the addition of supplementary charges being carried out during the course of crystallisation of the silicon, as a function of the height of the ingot. It can be seen from this curve 204 that the boron concentration gradually increases with crystallisation since the boron segregates during crystallisation, in accordance with the Scheil-Gulliver equation. The curve 206 represents the resistivity of the crystallised silicon as a function of the height of the ingot. It can be seen from this curve that the resistivity of the ingot falls towards zero when crystallisation ends, towards the top of the ingot.

The ingot obtained by regularly carrying out additions of supplementary charges during crystallisation of the silicon may therefore be used over its entire length to create substrates which are for example destined for photovoltaic cell manufacture. On the other hand, if it is desired to create substrates whose resistivity is between about 3.32 Ohm·cm and 2.6 Ohm·cm, that is, with a variation of 20% relative to the optimum value of 3.32 Ohm·cm, from the ingot created without addition of supplementary charges, only 68% of the ingot can be used. If a variation of 10% of the resistivity value can be tolerated, only 43% of this ingot can be used. Finally if a variation of 5% of the resistivity value can be tolerated, only 24% of the ingot may be used in the manufacture of these wafers, whereas the entire ingot crystallised with the addition of charges may be used.

A second embodiment of an uncompensated silicon n-type ingot will now be described, that is one which only contains phosphorous as a dopant species, and whose desired resistivity is equal to about 4.89 Ohm·cm.

The initially molten charge is made up of microelectronic silicon doped only with phosphorous at a concentration of 0.05 ppmw, (that is 2.28^{E}15 atoms/cm³). The mass of the first charge is equal to about half the final mass of the ingot. The supplementary charges that are added to the silicon bath during the crystallisation method are based on silicon also of the same electronic origin, also doped only with phosphorous, but which has a concentration equal to 0.005 ppmw. The total mass of these supplementary charges represents half of the final mass of the ingot.

The additions of supplementary charges are made each time the mass of the crystallised semiconductor increases by about 0.2% relative to the total mass of crystallised semiconductor obtained at the end of the crystallisation method. In this example these additions start when about 10% of the ingot has already crystallised.

The curve 300 in FIG. 3 represents the boron concentration in the crystallised silicon (right vertical axis) as a function of the ingot height (horizontal axis, with a normalised scale). Thus it can be seen that the crystallised silicon obtained exhibits a boron concentration which increases in the first 10% of the ingot, that is when no additions of supplementary charges have been made, and which then becomes constant up to about 85% of the height of the ingot when additions of supplementary charges are carried out. In an analogous manner, curve 302 in FIG. 3 represents the resistivity of the crystallised silicon (left vertical axis) as a function of the ingot height. It can be seen from this curve 302 that the crystallised silicon obtained exhibits a resistivity which falls over the first 10% of the ingot and which then becomes constant and equal to about 4.89 Ohm·cm up to about 85% of the height of the ingot.

In comparison, curve 304 represents the phosphorous concentration in an ingot of silicon obtained by crystallisation of a molten charge of microelectronic silicon doped with phosphorous at a concentration of 0.0578 ppmw, but without the addition of supplementary charges being made during the course of crystallisation of the ingot, as a function of the height of the ingot. It can be seen from this curve 304 that the phosphorous concentration in the crystallised silicon falls along the entire length of the ingot since the phosphorous segregates during crystallisation, in accordance with the Scheil-Gulliver equation. The curve 306 represents the resistivity of the silicon as a function of the height of this ingot. It can be seen from this curve that the resistivity of this ingot falls towards zero throughout the crystallisation.

If it is desired to create substrates whose resistivity varies at most by 20% relative to the optimum value of 4.89 Ohm·cm from the ingot obtained with additions of supplementary charges, 91% of the ingot can be used. In comparison, only 30% of the ingot created without additions of supplementary charges may be used in this case. If a variation of 10% of the resistivity value can be tolerated, then only 85% of the ingot made with the additions can be used, as against 15% of the ingot made without additions. Finally, if a variation of 5% of the resistivity value can be tolerated, 81% of the ingot obtained with additions can be used, whereas only 8% of the ingot made without additions can be used.

In the example described above, additions of supplementary charges are preferably made when about 10% of the total height of the ingot has already crystallised, since the first 10% of the ingot is generally stripped away. In one variant it is also possible for additions of supplementary charges to be carried out once crystallisation starts, but then stopped when about 90% of the total height of the ingot has crystallised.

A third embodiment of a compensated p-type silicon ingot will now be described, that is, one which contains both phosphorous and boron with a level of boron set at equal to about 2 ppmw, and whose desired resistivity is equal to about 0.63 Ohm·cm.

The initially molten charge is made up of purified silicon of metallurgical origin doped with boron at a concentration of 2 ppmw and with phosphorous at a concentration of 9.5 ppmw. This first charge weighs about half the final mass of the ingot. The supplementary charges that are added to the silicon bath during the crystallisation method are based on silicon also of metallurgical origin, also doped only with boron at a concentration of 2 ppmw, but which has a phosphorous concentration of 2 ppmw. The total mass of these supplementary charges represents half of the final mass of the ingot.

The additions of supplementary charges are carried out each time that the mass of the crystallised semiconductor increases by about 0.2% relative to the total solidified mass of semiconductor obtained at the end of the solidification method. In this example these additions start when about 10% of the ingot has already crystallised.

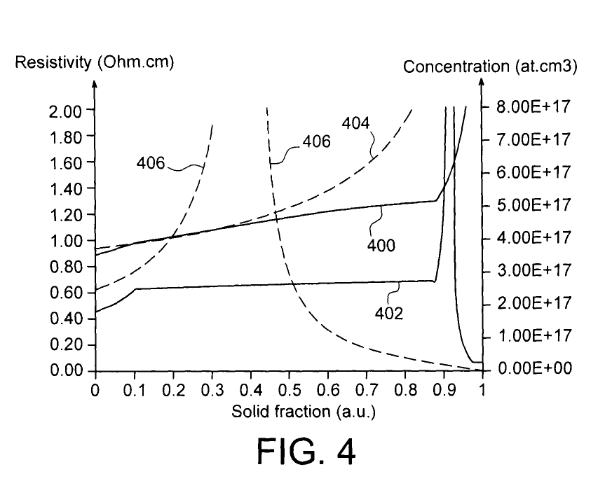

The curve 400 in FIG. 4 represents the total concentration of majority carriers na+nd in the crystallised silicon (right vertical axis) as a function of the ingot height (horizontal axis, with a normalised scale). Thus it can be seen that this concentration obtained increases relatively little as a result of additions of supplementary charges which dilutes these charges in the bath, up to about 85% of the height of the ingot. In an analogous manner, curve 402 in FIG. 4 represents the resistivity of the crystallised silicon (left vertical axis) as a function of the ingot height. It can be seen from this curve 402 that the ingot obtained exhibits a resistivity which increases over the first 10% of the ingot and which then becomes relatively constant around a value of 0.63 Ohm·cm as a result of the addition of supplementary charges, up to about 85% of the height of the ingot. A divergence in the type of conductivity takes place in an abrupt manner at about 92% of the total height of the silicon ingot as a result of the differences between the partition coefficients of the phosphorous and the boron, with the phosphorous segregating more than the boron. The last 8% of the ingot is therefore n-type.

In comparison, curve 404 represents the total concentration of majority carriers na+nd in an ingot of silicon obtained by crystallisation of a molten charge of purified metallurgical silicon doped with boron at a concentration of 2 ppmw and with phosphorous at a concentration of 10.42 pmmw, but without the addition of supplementary charges being carried out during the course of crystallisation of the ingot, as a function of the height of the ingot. It can be seen from this curve 404 that the na+nd concentration increases throughout crystallisation since the phosphorous and the boron segregate during crystallisation, in accordance with the Scheil-Gulliver equation. The curve 406 represents the resistivity of the crystallised silicon as a function of the height of the ingot. It can be seen from this curve that the resistivity of this silicon varies greatly and tends to infinity at around 39.5% of the ingot height, and then diverges and changes conductivity type (n-type).

If it is desired to create substrates whose resistivity varies at most by 20% relative to the optimum value of 0.63 Ohm·cm, from the ingot created with additions of supplementary charges, about 85% of the ingot can be used. In comparison, only 9% of the ingot created without additions of supplementary charges may be used in this case. If a variation of 10% of the resistivity value can be tolerated, then about 81% of the ingot made with the additions can be used, as against 5% of the ingot made without additions. Finally, if a variation of 5% of the resistivity value can be tolerated, about 44% of the ingot made with additions of supplementary charges can be used, whereas only 3% of the ingot made without additions can be used.

A fourth embodiment of a compensated p-type silicon ingot will now be described, that is one which contains both phosphorous and boron with a level of boron set to be equal to about 1 ppmw, and whose desired resistivity is equal to about 0.62 Ohm·cm.

The initially molten charge is made up of purified silicon of metallurgical origin doped with boron at a concentration equal to about 1 ppmw (that is 1.3^{E}17 atoms/cm³) and with phosphorous at a concentration equal to about 4 ppmw (1.82^{E}17 atoms/cm³). It weighs about half the final mass of the ingot. The supplementary charges that are added to the silicon bath during the crystallisation method are based on silicon which is also of metallurgical origin, also doped with boron at a concentration equal to about 1 ppmw, but which has a phosphorous concentration equal to about 2 ppmw. The total mass of these supplementary charges represents about half of the final mass of the ingot.

The additions of supplementary charges is carried out each time the mass of the crystallised semiconductor increases by about 0.2% relative to the total mass of crystallised semiconductor obtained at the end of the crystallisation method. In this example these additions start when about 10% of the ingot has already crystallised.

In this case the change in the type of conductivity takes place at about 86% of the total height of the ingot. In comparison, by making an ingot without additions of supplementary charges during crystallisation from a charge of purified metallurgical silicon doped with boron at a concentration equal to about 1 ppmw and with phosphorous at a concentration equal to about 4.35 ppmw, a change in the type of conductivity is then observed at about 59.5% of the height of the ingot.

If it is desired to create substrates whose resistivity varies at most by 20% relative to the optimum value of 0.62 Ohm·cm from the ingot created with additions of supplementary charges, about 73% of the ingot can be used. In comparison, only 18% of the ingot created without additions of supplementary charges may be used in this case. If a variation of 10% of the resistivity value can be tolerated, then about 68% of the ingot made with the additions can be used, as against 11% of the ingot made without additions. Finally, if a variation of 5% of the resistivity value can be tolerated, about 64% of the ingot made with additions can be used, whereas only 6% of the ingot made without additions can be used.

In the third and fourth examples above, it will be seen that the more boron that is contained in the initial charge, the more the phosphorous concentration that is required to maintain the same resistivity increases. This method is therefore of even greater interest if one has charges which are rich in boron (and therefore rich in phosphorous for a given resistivity). For example, with an initial charge with a boron concentration equal to about 4 ppmw and a comparable resistivity of 0.63 Ohm·cm, this first charge will then have a phosphorous concentration equal to about 22.8 ppmw. In this case the transition to n-type will take place at towards 27% of the ingot. The addition of supplementary charges with 4 ppmw of boron and 4 ppmw of phosphorous allows a much more abrupt change to n-type at 91% of the ingot, given that the resistivity value before the transition at 90% of the ingot is 0.67 Ohm·cm.

1. A method for semiconductor solidification which includes at least steps for:
forming a bath of molten semiconductor from at least one first charge of semiconductor which includes dopants,
solidification of the molten semiconductor,
and which in addition includes, during the course of solidification of the molten semiconductor, the implementation, during at least part of the solidification method, of one or more steps for the addition of one or more supplementary charges of the semiconductor, also containing dopants, to the molten semiconductor bath (103), which lowers the variability of the value of the
$${\sum }_{i = 1}^{n} {k}_{i} {C}_{L}^{i} - {\sum }_{j = 1}^{m} {k}_{j} {C}_{L}^{j}$$
term of the molten semiconductor in the bath relative to the variability naturally achieved by the values of the partition coefficients for the dopant species such that:
$$( {\sum }_{i = 1}^{n} {k}_{i} {C}_{a}^{i} - {\sum }_{j = 1}^{m} {k}_{j} {C}_{a}^{j} ) < ( {\sum }_{i = 1}^{n} {k}_{i} {C}_{L}^{i} - {\sum }_{j = 1}^{m} {k}_{j} {C}_{L}^{j} ) if$$
$${\sum }_{i = 1}^{n} {k}_{i} ( 1 - {k}_{i} ) {C}_{L}^{i} > {\sum }_{j = 1}^{m} {k}_{j} ( 1 - {k}_{j} ) {C}_{L}^{j} \\ ( {\sum }_{i = 1}^{n} {k}_{i} {C}_{a}^{i} - {\sum }_{j = 1}^{m} {k}_{j} {C}_{a}^{j} ) > ( {\sum }_{i = 1}^{n} {k}_{i} {C}_{L}^{i} - {\sum }_{j = 1}^{m} {k}_{j} {C}_{L}^{j} ) if$$
$${\sum }_{i = 1}^{n} {k}_{i} ( 1 - {k}_{i} ) {C}_{L}^{i} < {\sum }_{j = 1}^{m} {k}_{j} ( 1 - {k}_{j} ) {C}_{L}^{j}$$
and which lowers the variability of the value of the
$${\sum }_{i = 1}^{n} {k}_{i} {C}_{L}^{i} - {\sum }_{j = 1}^{m} {k}_{j} {C}_{L}^{j}$$
term of the molten semiconductor in the bath relative to the variability achieved by the addition of pure dopant species such that:
$${\sum }_{i = 1}^{n} {k}_{i} {C}_{a}^{i} - {\sum }_{i = 1}^{n} {k}_{i} {C}_{L}^{i} and$$
$${\sum }_{j = 1}^{m} {k}_{j} {C}_{a}^{j} < 2 {\sum }_{i = 1}^{n + m} {k}_{i} {C}_{L}^{i} if$$
$${\sum }_{i = 1}^{n} {k}_{i} ( 1 - {k}_{i} ) {C}_{L}^{i} > {\sum }_{j = 1}^{m} {k}_{j} ( 1 - {k}_{j} ) {C}_{L}^{j} ;$$
$${\sum }_{j = 1}^{m} {k}_{j} {C}_{a}^{j} < {\sum }_{j = 1}^{m} {k}_{j} {C}_{L}^{j} and$$
$${\sum }_{i = 1}^{n} {k}_{i} {C}_{a}^{i} < 2 {\sum }_{i = 1}^{n + m} {k}_{i} {C}_{L}^{i} if$$
$${\sum }_{i = 1}^{n} {k}_{i} ( 1 - {k}_{i} ) {C}_{L}^{i} < {\sum }_{j = 1}^{m} {k}_{j} ( 1 - {k}_{j} ) {C}_{L}^{j} ;$$
where C_{L}ⁱ: concentration of electron acceptor dopants i in the molten semiconductor bath;
C_{L}^{j}: concentration of electron donor dopants j in the molten semiconductor bath;
Cₐⁱ: concentration of electron acceptor dopants i in the supplementary added charge or charges;
Cₐ^{j}: concentration of electron donor dopants j in the supplementary added charge or charges;
kᵢ: partition coefficient of the electron acceptor dopants i,
kⱼ: partition coefficient of the electron donor dopants j,

2. The semiconductor solidification method according to claim 1, in which electron acceptor dopants i are atoms of boron and electron donor dopants j are atoms of phosphorous.

3. The semiconductor solidification method according to claim 2, in which the supplementary semiconductor charge or charges are added whilst ensuring that the following relationships hold:
$${C}_{a}^{P} = {C}_{a}^{B} \frac{( 1 - {k}_{P} ) {C}_{L}^{P}}{( 1 - {k}_{B} ) {C}_{L}^{B}} + {C}_{L}^{P} * \frac{( {k}_{P} - {k}_{B} )}{( 1 - {k}_{B} )} , and$$
$$\frac{d {m}_{a}}{d {m}_{S}} = \frac{{C}_{L}^{B} ( 1 - {k}_{B} )}{( {C}_{L}^{B} - {C}_{a}^{B} )} > 1 - {k}_{P} , where \text{:}$$
$$d {m}_{a} / d t \text{:} addition speed in kg \text{/} s$$
$$d {m}_{S} / d t \text{:} crystallisation speed in kg \text{/} s$$

4. The semiconductor solidification method according to claim 3, in which the supplementary semiconductor charge or charges are added at an addition speed which is less than the speed of crystallisation, which verifies:
Cₐ^{P}<k_{P}C_{L}^{P} and Cₐ^{B}<k_{B}C_{L}^{B}

5. The semiconductor solidification method according to claim 1, in which the supplementary semiconductor charge or charges are added to the semiconductor bath in solid form, and are then fused and mixed with the molten semiconductor bath.

6. The semiconductor solidification method according to claim 1, in which the supplementary semiconductor charge or charges are added to the semiconductor bath in liquid form during at least part of the solidification method.

7. The semiconductor solidification method according to claim 1, in which, when several supplementary semiconductor charges are added during solidification, a supplementary semiconductor charge is added each time that the mass of solidified semiconductor increases by at most 1% in relation to the total mass of solidified semiconductor obtained at the end of the solidification method.

8. The semiconductor solidification method according to claim 1, where the steps in said solidification method are carried out in a Bridgman type furnace, where the semiconductor bath is located in a crucible of said furnace.

9. The semiconductor solidification method according to claim 8, in which the furnace includes a closed enclosure which is under an argon atmosphere in which the crucible is placed.

10. The semiconductor solidification method according to claim 1, in which, when the supplementary semiconductor charge or charges are added to the semiconductor bath in solid form, this addition or these additions are carried out using a distribution device which also carries out pre-heating of the supplementary semiconductor charge or charges.

11. The semiconductor solidification method according to claim 7, in which the moments in time at which the addition or additions of the supplementary semiconductor charge or charges are made are determined by the means of control of the distribution device.

12. The semiconductor solidification method according to claim 1, in which the concentration of at least one type of dopant in the first semiconductor charge is different from the concentration of this same type of dopant in the supplementary semiconductor charge or charges.

13. The semiconductor solidification method according to claim 1, in which the molten semiconductor is solidified in the form of an ingot or a ribbon.
